(19) United States
(12) Patent Application Publication
(10) Pub. No.: US 2013/0322034 A1
(43) Pub. Date: Dec. 5, 2013

(54) Method of Manufacturing a Surface Mounted Device and Corresponding Surface Mounted Device

(71) Applicant: Francois Lechleiter, Favrieux (FR)

(72) Inventor: Francois Lechleiter, Favrieux (FR)

(73) Assignee: Linxens Holding, Guyancourt (FR)

(21) Appl. No.: 13/996,051

(22) PCT Filed: Oct. 13, 2011
(86) PCT No.: PCT/EP2011/067941

§ 371 Date: Aug. 6, 2013

(30) Foreign Application Priority Data
Dec. 21, 2010 (IB) PCT/IB2010/003533

(51) Int. Cl. H05K 3/34; H05K 1/02

(52) U.S. Cl. CPC H05K 3/341; H05K 1/0277
USPC 361/749; 29/832

(57) ABSTRACT

The inventions relates to a method of manufacturing a flexible surface mounted device, the method including bonding a main face of a conductive layer to an insulating layer; linking electrically and mechanically at least one electronic surface mounted component to the conductive layer; wherein the insulating layer is punched to produce through holes through which the electronic component is linked to said main face of the conductive layer.

### FIELD OF THE INVENTION

The invention relates to a method of manufacturing a surface mounted device and a surface mounted device manufactured by this method.

### BACKGROUND OF THE INVENTION

A Printed Circuit Board or PCB, is used to mechanically support and electrically connect electronic components. A surface mounted device is a PCB having electronic components mounted directly onto its surface.

Originally, a method of manufacturing such surface mounted devices called through-hole construction was used. According to this method, the electronic components have wire leads that were inserted into holes (PTH-Plated Through Hole) drilled in a wafer either by manual assembly by hand placement or by the use of automated insertion mount machines. The wire leads of the electronic components were then soldered to pads located on the side of the wafer opposite to the side of the wafer carrying the electronic components.

Nowadays, a method of manufacturing such surface mounted devices, called Surface Mount Technology (SMT), is used. According to this method, a conductive layer, usually made of copper, is bonded over its entire surface to an insulated layer. A temporary mask is applied on the conductive layer and unwanted copper is removed, for example, by etching to construct an interconnection pattern. This interconnection pattern comprises interconnection pathways and flat pads without holes, called solder pads. Solder paste is applied on the solder pads with a stainless steel or a nickel stencil using, for example, a screen printing process. After screen printing, the leads (which have no wire) of the electronic components are placed on the solder paste usually by pick-and-place machines. Afterwards, the wafers are conveyed into a reflow soldering oven to bond the electronic component leads to the solder pads.

However, since the electronic components are small, around 0.4×0.2 mm, some electronic components may be lifted or shifted from the solder pads which leads to weak connexions.

To remedy to this drawback, one technique consists in covering the interconnection pathways of the interconnection pattern with a solder resist before applying the solder paste. The solder resist is applied to build up retain walls around the solder pads wherein the solder paste is filled for example by the stencil.

However, this method is quite expensive due to the use of a solder resist. Further, this method requires the application of a second mask on the conductive layer.

In parallel, it has been known to manufacture flexible printed circuits, using continuous roll-to-roll processes, for example to produce flexible circuits such as circuits comprising contacts for smartcards.

### SUMMARY OF THE INVENTION

The invention seeks to mitigate at least one these drawbacks by proposing a manufacturing method which is more efficient.

The invention thus relates to a method of manufacturing a flexible surface mounted device. A main face of a conductive layer is bonded to an insulating flexible layer.

One or more electronic surface-mounted component is/are electrically and mechanically linked to the conductive layer.

Through holes are produced in the insulating layer. The electronic surface-mounted component(s) are linked to the main face of the conductive layer through these through holes.

With this feature, surface mounted devices can be manufactured without using a solder resist and even without the use of a stencil for placing the solder resist.

As a result, the manufacturing process is cheaper and more reliable.

According to another aspect, the invention relates to a flexible surface mounted device. This device comprises a conductive layer and a flexible insulating layer stacked and bonded to the conductive layer. One or more electronic surface mounted component(s) is/are electrically and mechanically linked to the conductive layer. The electronic surface mounted component(s) is/are linked to the conductive layer via connexion passing through through-holes formed into the insulating layer.

### BRIEF DESCRIPTION OF THE DRAWINGS

Other characteristics and advantages of the invention will readily appear from the following description of one of its embodiments, provided as a non-limitative example, and of the accompanied drawings.

On the drawings :

FIG. 1 is a flow chart illustrating the manufacturing steps of the method according to the invention;

FIGS. 2 to 7 are cross-sectional schematic views of a part of a surface mounted device at different manufacturing steps; and

FIG. 8 is a front schematic view of a band comprising surface mounted device to cut.

On the different figures, the same references signs designate like or similar elements.

### DETAILED DESCRIPTION

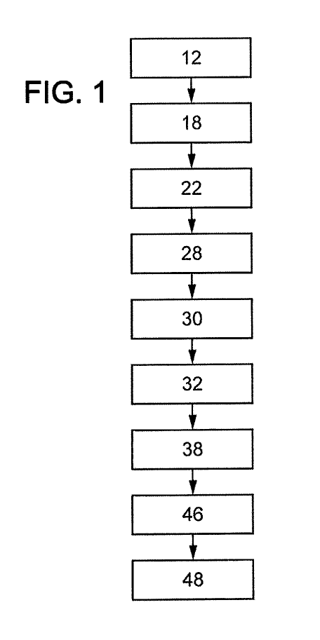

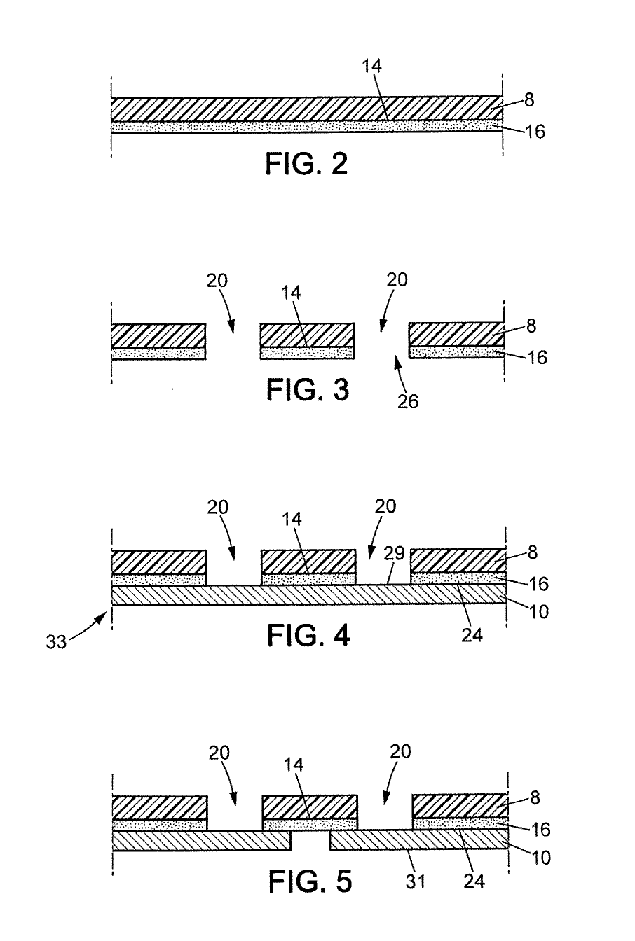

In reference to FIGS. 1 and 2, the manufacturing method according to the invention begins with a step 12 of spreading glue 16 on a first main face 14 of an insulating layer 8.

The insulating layer 8 is made of a dielectric polymeric material, for example, glass epoxy material. This insulating layer 8 will form the substrate on which the electronic components will be electrically and mechanically connected. The insulating layer 8 has for example, a width of 8 to 10 mm and a thickness in the range of 50 to 250 μm, and more particularly in the range of 75 to 110 μm.

Then, at step 18, the insulating layer 8 is punched to produce through holes 20, as shown on FIG. 3. The through holes are drilled on locations where leads of electronic components have to be fixed to produce the desired device. Such holes have a size with the millimetre as an order of magnitude. For example, they are about 0.5 mm to 5 mm in size. For simplification reason, FIGS. 2 to 7 show only a short part of a band on which one electronic component is mounted. The manufacturing method according to the invention is performed on a greater band surface on which several electronic components are electrically and mechanically connected to produce the device.

At step 22, a main face 24 of a conductive layer 10 is stacked on the glue-spreaded face 14 of the insulating layer and is bonded to it by adhesion and lamination to produce a flexible band 33.

The conductive layer 10 is, for example, a flexible layer of copper having a width of 8 to 10 mm and a thickness in the range of 10 to 30 μm.

As a result, at least one of the openings 26 of the through-holes 20 is covered with the conductive layer 10. The through holes 20 are now blind holes having bottom regions 29 made of conductive material as shown on FIG. 4. Preliminary to its fixation, the main face 24 of the conductive layer might be treated by suitable treatments.

At step 28, the bottom regions 29 of the conductive layer are deoxidized, i.e., the regions of the main face 24 delimited by the through-holes are deoxidized.

In variant, the entire main face 24 of the conductive layer is deoxidized. According to this variant, the deoxidization step 28 is performed before the bonding step 22.

At step 30, the conductive layer 10 is patterned, for example by screen printing, photoengraving or PCB milling to create an interconnection pattern, i.e. to create conductor pathways which will link the electronic components between them according to the desired electronic figure, as partially shown on FIG. 5. Afterwards, the main face 31 of the conductive layer opposite to the main face 24 is protected, for example, by applying a conformal coating by dipping or spraying. This coating prevents corrosion and leakage currents or shorting due to condensation.

At step 32, a solder paste 34 is brought in the blind holes 20. To this end, the solder paste 34 is advantageously dispensed by scraping. The solder paste is, for example, deposited on the surface 44 of the insulating substrate and is pushed into the hole 20 by a fixed squeegee 36 as shown on FIG. 6.

The squeegee scraps the excess solder paste away from the opening 20. At step 38, an electronic surface-mounted component 40 is placed on the wafer 31 with its leads 42 in contact to the solder paste 34, for example by a pick-and-place machine. In particular, the electronic surface-mounted component 40 is placed in contact with the main face 44 of the insulating layer 8 which is opposite to the main face 24 bonded to the conductive layer 10.

The surface-mounted component has dimensions of at least 5 mm, with electrical contact sizes of about 0.1 to 1 mm.

As shown on FIG. 7, the leads 42 of the electronic component are made of flat pads. These leads 42 do not comprise any wire.

The electronic components comprise, for example, transistors, resistors printed circuit boards or light emitting diodes.

At step 46, the wafer 31 is submitted to reflow-soldering to melt the solder paste 34 for soldering the component leads 42. After reflow soldering, the solder paste 34 forms an electrical and mechanical connexion 47 between the electronic component 40 and the main face 24 of the conductive layer 10.

Hence, the insulating layer itself is used as a solder mask. The surface-mounted components 40 are connected by way of the conductive layer 10 provided on the bottom face.

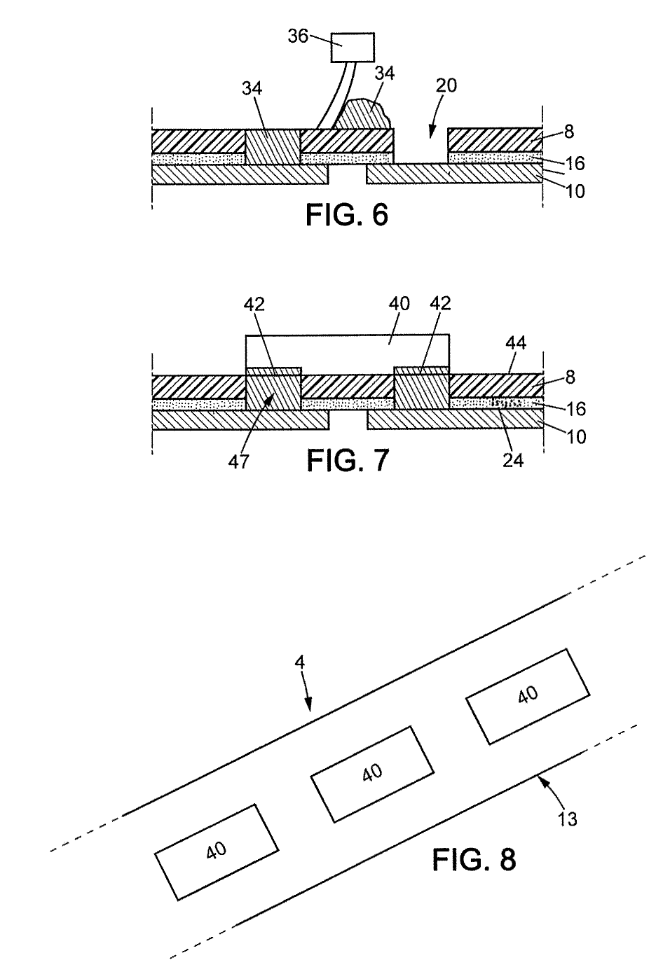

Thus, the insulating layer 8, the conductive layer 10 and the electronic components linked to them constitute a flat band 13.. The flat band 13 comprises surface mounted devices 4 to be cut free from the band, as shown on FIG. 8. This band 13 is delivered to a client who cuts, at step 48 the required surface mounted devices 4. Alternatively, the surface mounted devices 4 are cut before being delivered to clients.

The steps described above are performed in a plurality of continuous apparatus disposed in series or in parallel.

The surface mounted device 4 is, for example, a band of light emitting diodes. In this case, the electrical connexions to the LEDs are not visible, so that the lighting effect is better. For example, when the surface mounted device is a light emitting diode band, sections of several centimetres comprising several light emitting diodes are cut in band 13.

The invention is also related to a surface mounted device 4 manufactured by the above-mentioned method. This surface mounted flexible device 4 comprises a conductive layer 10, an insulating layer 8 bonded to the conductive layer 10, for example with glue and at least one electronic surface-mounted component 40 electrically and mechanically linked to the conductive layer 10 via through holes 20 punched into the insulating layer.

1. A method of manufacturing a flexible surface mounted device, the method comprising:
bonding a main face of a conductive layer to an insulating flexible layer;
electrically and mechanically linking at least one electronic surface-mounted component to the conductive layer;
producing through holes in the insulating layer, the electronic surface-mounted component being linked to said main face of the conductive layer through said through holes.

2. A method according to claim 1, wherein the step of producing through holes comprises a punching step which is performed preliminary to the bonding step; the conductive layer covering one of the openings of the through holes.

3. A method according to claim 1, wherein it comprises deoxidizing at least one region of said main face of the conductive layer.

4. A method according to claim 3, wherein said deoxidized region is delimited by a through hole.

5. A method according to claim 1, wherein the conductive layer and the insulating layer are cut free from a band, to produce the surface mounted device.

6. A method of manufacturing a flexible surface mounted device comprising:
bonding a main face of a conductive layer to an insulating flexible layer;
electrically and mechanically linking at least one electronic surface mounted component to the conductive layer;
wherein the insulating layer is punched to produce through holes through which the electronic surface mounted component is linked to said main face of the conductive layer, and wherein the conductive layer is bonded to a first main face of the insulating layer; and the electronic surface mounted component is carried by a second main face of the insulated layer, the second main face being opposite to the first main face.

7. A method according to claim 6, wherein the linking step comprises:
bringing solder paste in the through holes;
placing leads of the electronic surface mounted component on the solder paste;
reflow soldering of the leads of the electronic component to the conductive layer; the solder paste forming, after reflow soldering, a mechanical and electrical connexion between the electronic component and said main face of the conductive layer.

8. A method according to claim 7, wherein the bringing step is performed by application of solder paste with a squeegee

9. A method according to claim 1, wherein at least the bonding and the producing steps are performed repeatedly in a roll-to-roll apparatus.

10. A flexible surface mounted device, comprising a conductive layer, a flexible insulating layer stacked and bonded to the conductive layer; at least one electronic surface mounted component electrically and mechanically linked to the conductive layer wherein the electronic surface mounted component is linked to the conductive layer via connexion passing through through-holes formed into the insulating layer.

11. A surface mounted device according to claim 10, wherein the electronic surface mounted component is positioned on a first main face of the insulating layer and the conductive layer is positioned on a second main face of the insulating layer; the second main face being opposite to the first main face.

12. A surface mounted device according to any of the claims claim 10, wherein the electronic surface mounted component is a light emitting diode.

13. A surface mounted device according to claim 10 comprising at least two electronic surface mounted components, wherein the two electronic surface mounted components are electrically connected to one another by way of the conductive layer.
